(19) United States
(12) Patent Application Publication
(10) Pub. No.: US 2025/0187043 A1
(43) Pub. Date: Jun. 12, 2025

(54) SUBSTRATE PROCESSING APPARATUS AND SUBSTRATE PROCESSING METHOD USING THE SAME

(71) Applicant: Samsung Electronics Co., Ltd., Suwon-si (KR)

(72) Inventors: AHRA JEON, Suwon-si (KR); SUNG YONG PARK, Suwon-si (KR); JAEMIN JUNG, Suwon-si (KR); HOSEOP CHOI, Suwon-si (KR)

(21) Appl. No.: 18/781,171

(22) Filed: Jul. 23, 2024

(30) Foreign Application Priority Data
Dec. 12, 2023 (KR) 10-2023-0180085

(51) Int. Cl. B08B 5/00; B08B 3/04; H01L 21/67

(52) U.S. Cl. CPC B08B 5/00; B08B 3/04; H01L 21/67051

(57) ABSTRACT

Disclosed are substrate processing apparatuses and methods. The substrate processing apparatus comprises a first process chamber including a first process space, a stage in the first process space and being configured to support a substrate, a stage driving mechanism configured to drive the stage to rotate about a first axis, a cleaning nozzle arm configured to supply a cleaning solution onto the stage, a gas supply unit configured to provide an inert gas to the first process space, and an airflow generator between the stage and the gas supply unit and being configured to generate a spiral-shaped rotating air current.

### CROSS-REFERENCE TO RELATED APPLICATION

This U.S. nonprovisional application claims priority under 35 U.S.C. § 119 to Korean Patent Application No. 10-2023-0180085 filed on Dec. 12, 2023, in the Korean Intellectual Property Office, the disclosure of which is hereby incorporated by reference in its entirety.

### BACKGROUND

The present inventive concepts relate to a substrate processing apparatus and a substrate processing method using the same, and more particularly, to a substrate processing apparatus capable of creating an inert gas environment in a process chamber to reduce or prevent corrosion and substrate metal oxidation reactions caused by oxygen and capable of reducing a space required to be filled in a process chamber and generating rotating air currents and a substrate processing method using the same.

A semiconductor device may be fabricated through various processes. It may be needed to clean surfaces of substrates for performing subsequent processes after completion of processes such as deposition and etching processes. For cleaning of substrates, an inert gas may fill an internal space of a process chamber and an etching solution may be sprayed to substrate surfaces. A stage which supports the substrate may be allowed to rotate to turn the substrate, and this may eliminate the cleaning solution and foreign substances present on the substrate surface.

### SUMMARY

Some embodiments of the present inventive concepts provide a substrate processing apparatus including an airflow generator capable of producing a rotating air current in a process chamber and a substrate processing method using the same.

Some embodiments of the present inventive concepts provide a substrate processing apparatus configured to supply a chamber with an inert gas during a cleaning procedure to reduce or prevent corrosion and substrate metal oxidation reactions caused by ambient oxygen and dissolved oxygen in a cleaning solution and a substrate processing method using the same.

Some embodiments of the present inventive concepts provide a substrate processing apparatus configured to create a rotating air current to effectively eliminate foreign substances and a substrate processing method using the same.

Some embodiments of the present inventive concepts provide a substrate processing apparatus including a propeller or a showerhead and a substrate processing method using the same.

Some embodiments of the present inventive concepts provide a substrate processing apparatus capable of reducing the volume of a process space to be filled with an inert gas and a substrate processing method using the same.

The object of the present inventive concepts is not limited to the mentioned above, and other objects which have not been mentioned above will be clearly understood to those skilled in the art from the following description.

According to some embodiments of the present inventive concepts, a substrate processing apparatus may comprise: a first process chamber including a first process space; a stage in the first process space and configured to support a substrate; a stage driving mechanism configured to drive the stage to rotate about a first axis; a cleaning nozzle arm configured to supply a cleaning solution onto the stage; a gas supply unit configured to provide an inert gas to the first process space; and an airflow generator between the stage and the gas supply unit and configured to generate a spiral-shaped rotating air current.

According to some embodiments of the present inventive concepts, a substrate processing apparatus may comprise: a first process chamber including a first process space; a stage in the first process space and configured to support a substrate; a cleaning nozzle arm in the first process space and upwardly spaced apart from the stage; a gas supply unit configured to supply the first process space with an inert gas; and an airflow generator on the stage configured to create a spiral-shaped rotating air current. The airflow generator may include a showerhead comprising a gas hole configured to uniformly spray the inert gas on the stage.

According to some embodiments of the present inventive concepts, a substrate processing method may comprise: placing a substrate in a substrate processing apparatus; generating a rotating air current on the substrate; and cleaning the substrate. The substrate processing apparatus may include: a first process chamber including a first process space; a rotatable stage in the first process space; a cleaning nozzle arm configured to supply a cleaning solution onto the stage; a gas supply unit configured to supply the first process space with an inert gas; and an airflow generator on the stage and configured to generate the rotating air current that is spiral-shaped. The airflow generator may include a showerhead comprising a gas hole through which the inert gas passes. The step of generating the rotating air current may include using the gas supply unit to spray the inert gas toward the showerhead. The step of generating the rotating air current may further include rotating the airflow generator or passing the inert gas through the gas hole. The gas hole may be curved shaped.

Details of other example embodiments are included in the description and drawings.

### BRIEF DESCRIPTION OF DRAWINGS

FIG. 1 illustrates a perspective view showing a substrate processing apparatus according to some embodiments of the present inventive concepts.

FIG. 2 illustrates a perspective view showing a substrate processing apparatus according to some embodiments of the present inventive concepts.

FIG. 3 illustrates a cross-sectional view showing a substrate processing apparatus according to some embodiments of the present inventive concepts.

FIG. 4 illustrates a perspective view showing a substrate processing apparatus according to some embodiments of the present inventive concepts.

FIG. 5 illustrates a perspective view showing a substrate processing apparatus according to some embodiments of the present inventive concepts.

FIG. 6 illustrates a perspective view showing a substrate processing apparatus according to some embodiments of the present inventive concepts.

FIG. 7 illustrates a side view showing a substrate processing apparatus according to some embodiments of the present inventive concepts.

FIG. 8 illustrates a plan view showing a showerhead on which an extending direction of a gas hole is expressed according to some embodiments of the present inventive concepts.

FIG. 9 illustrates a side view showing a showerhead according to some embodiments of the present inventive concepts.

FIG. 10 illustrates a perspective view showing a substrate processing apparatus according to some embodiments of the present inventive concepts.

FIG. 11 illustrates a cross-sectional view showing a substrate processing apparatus according to some embodiments of the present inventive concepts.

FIG. 12 illustrates a perspective view showing a substrate processing apparatus according to some embodiments of the present inventive concepts.

FIG. 13 illustrates a cross-sectional view showing a substrate processing apparatus according to some embodiments of the present inventive concepts.

FIG. 14 illustrates a perspective view showing a substrate processing apparatus according to some embodiments of the present inventive concepts.

FIG. 15 illustrates a cross-sectional view showing a substrate processing apparatus according to some embodiments of the present inventive concepts.

FIG. 16 illustrates a flow chart showing a substrate processing method according to some embodiments of the present inventive concepts.

FIG. 17 illustrates a perspective view showing a substrate processing apparatus according to some embodiments of the present inventive concepts.

FIG. 18 illustrates a perspective view showing a substrate processing apparatus according to some embodiments of the present inventive concepts.

FIG. 19 illustrates a perspective view showing a substrate processing apparatus according to some embodiments of the present inventive concepts.

FIG. 20 illustrates a perspective view showing a substrate processing apparatus according to some embodiments of the present inventive concepts.

### DETAILED DESCRIPTION OF EMBODIMENTS

The following will now describe some embodiments of the present inventive concepts with reference to the accompanying drawings. Like reference numerals may indicate like components throughout the description.

In this description, symbol D1 may indicate a first direction, symbol D2 may indicate a second direction that intersects the first direction D1, and symbol D3 may indicate a third direction that intersects each of the first direction D1 and the second direction D2. The first direction D1 may be called an upward direction, and a direction opposite to the first direction D1 may be called a downward direction. The first direction D1 and its opposite direction may be called a vertical direction. In addition, each of the second direction D2 and the third direction D3 may be called a horizontal direction.

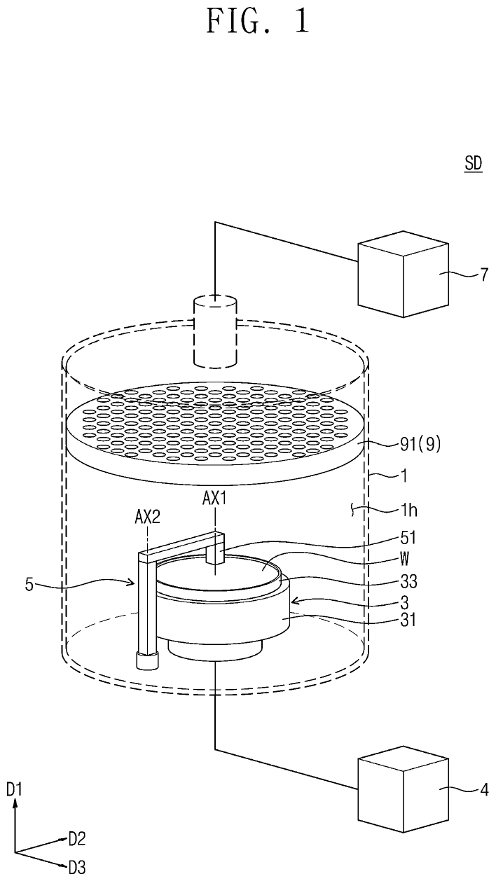

FIG. 1 illustrates a perspective view showing a substrate processing apparatus SD according to some embodiments of the present inventive concepts.

Referring to FIG. 1, the substrate processing apparatus SD may include a first process chamber 1, a stage 3, a stage driving mechanism 4, a cleaning nozzle arm 5, a gas supply unit 7, and an airflow generator 9.

The first process chamber 1 may provide a first process space 1h. The first process space 1h may be hermetically sealed. A substrate W may undergo a process performed in the first process space 1h. In this description, the substrate W may indicate a silicon (Si) wafer, but the present inventive concepts are not limited thereto. The first process space 1h may be isolated from an external space. The first process chamber 1 may be separated to introduce the substrate W from the external space into the first process space 1h. The first process chamber 1 may include a substrate introduction aperture through which the substrate W is introduced from the external space into the first process space 1h. The first process chamber 1 may have a cylindrical shape, but the present inventive concepts are not limited thereto.

The stage 3 may be positioned in the first process chamber 1. The stage 3 may be in the first process space 1h. The stage 3 may support and/or hold the substrate W. A substrate process may be performed in a state where the substrate W is placed on the stage 3. The stage 3 may include a stage body 31 and a substrate support 33. The stage body 31 may include an aluminum nitride (AlN) or aluminum (Al). The present inventive concepts, however, are not limited thereto. The stage body 31 may further include a material having high heat-resistance and high corrosion-resistance. The stage body 31 may have a disk shape, but the present inventive concepts are not limited thereto. The stage body 31 may have a diameter greater than that of the substrate W. For example, the stage body 31 may have a diameter of equal to or greater than about 300 mm. The substrate support 33 may cause the substrate W to lie spaced apart from a top surface of the stage body 31. The stage driving mechanism 4 may drive the stage 3 to rotate. For example, the stage driving mechanism 4 may force the stage 3 to rotate about a first axis AX1 in a clockwise direction or a counterclockwise direction. The first axis AX1 may pass through a center of the stage 3 and extend perpendicularly to the top surface of the stage body 31.

The cleaning nozzle arm 5 may spray a cleaning solution toward the stage 3. The cleaning nozzle arm 5 may supply the cleaning solution onto the stage 3. The cleaning solution sprayed from the cleaning nozzle arm 5 may include one of deionized (DI) water, organic solvents, and chemical solutions. The organic solvent may include one of ether, acetate, alcohol, and isopropyl alcohol (IPA). The kind of the organic solvent, however, is not limited thereto. The organic solvent may further include any other materials that can be mixed with hydrophilic and hydrophobic substances. The organic solvent may further include any other materials that can mix hydrophilic and hydrophobic substances with each other. A surface tension of the organic solvent at room temperature may be equal to or less than about 72 dynes/cm. The chemical solution may remove an oxide layer. The chemical solution may be a hydrofluoric acid. The hydrofluoric acid may be an aqueous solution of hydrogen fluoride. The present inventive concepts, however, are not limited thereto. The chemical solution may be a hydrofluoric acid compound including a hydrofluoric acid. The chemical solution may include a hydrogen fluoride compound. The chemical solution may include not one kind but many kinds.

The cleaning nozzle arm 5 may be positioned in the first process chamber 1. The cleaning nozzle arm 5 may be in the first process space 1h. The cleaning nozzle arm 5 may be positioned on the stage 3. The cleaning nozzle arm 5 may be upwardly spaced apart from the stage 3. The cleaning nozzle arm 5 may rotate about a second axis AX2 parallel to the first axis AX1. The cleaning nozzle arm 5 may include a cleaning nozzle 51. The cleaning nozzle 51 may spray a cleaning solution. The cleaning nozzle 51 may vertically extend toward the stage 3. The cleaning nozzle 51 may extend toward the substrate W in a direction of the first axis AX1.

The gas supply unit 7 may provide an inert gas to the first process space 1h. The gas supply unit 7 may be associated with the first process chamber 1. The gas supply unit 7 may be combined with or provided as a part of a top surface of the first process chamber 1. The present inventive concepts, however, are not limited thereto. The gas supply unit 7 may be at any other positions capable of uniformly providing the inert gas to the first process space 1h. The inert gas may include one or more of nitrogen (N₂), helium (He), and argon (Ar). The gas supply unit 7 may include a gas pump capable of providing the inert gas to the first process space 1h.

The airflow generator 9 may generate a spiral-shaped rotating air current in the first process space 1h. The rotating air current may be an airflow of the inert gas. The airflow generator 9 may be positioned between the stage 3 and the gas supply unit 7. A configuration and structure of the airflow generator 9 will be discussed in detail below.

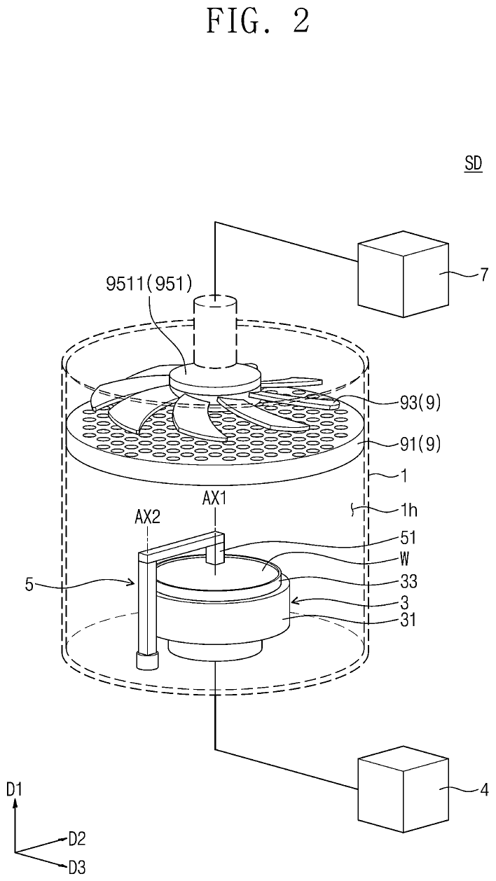

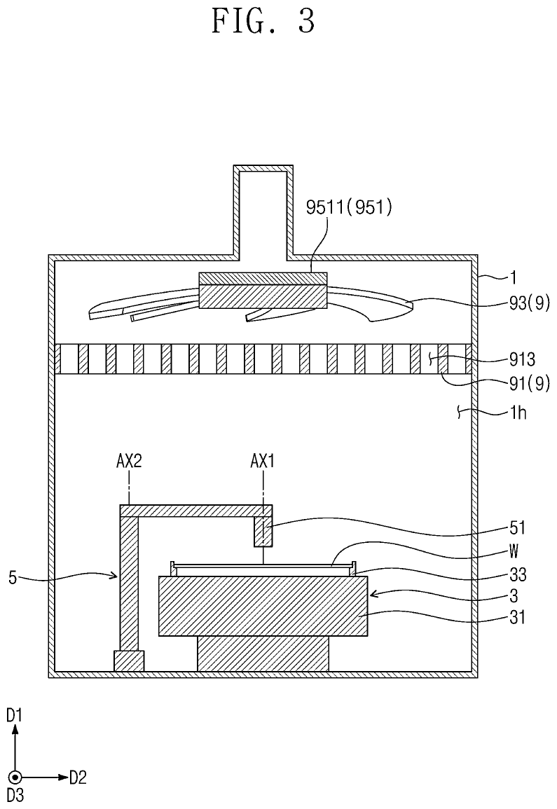

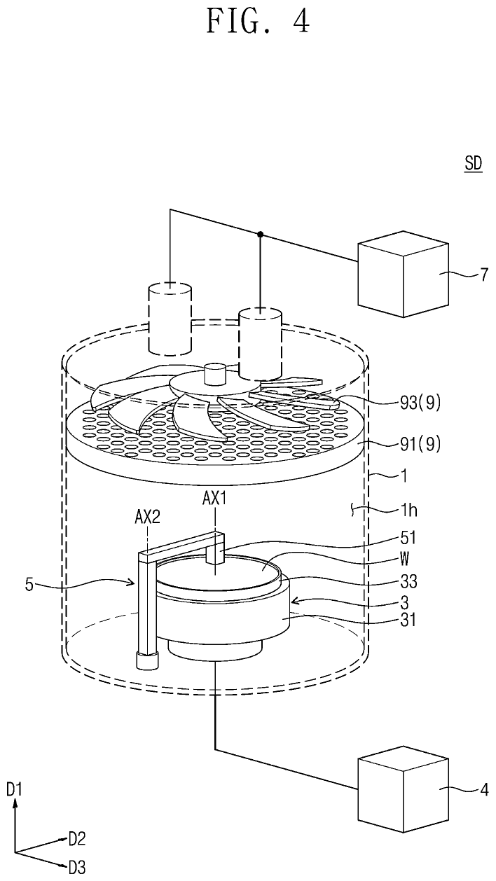

FIG. 2 illustrates a perspective view showing the substrate processing apparatus SD according to some embodiments of the present inventive concepts. FIG. 3 illustrates a cross-sectional view showing the substrate processing apparatus SD according to some embodiments of the present inventive concepts. FIG. 4 illustrates a perspective view showing the substrate processing apparatus SD according to some embodiments of the present inventive concepts.

Referring to FIGS. 2, 3, and 4, the substrate processing apparatus SD may be provided which includes a propeller 93 and a showerhead 91. The airflow generator 9 may include the propeller 93 and the showerhead 91. The showerhead 91 will be discussed below. The propeller 93 may rotate to form a rotating air current. The propeller 93 may form a spiral-shaped rotating air current. The propeller 93 may be positioned on the showerhead 91. The position of the propeller 93, however, is not limited thereto. The propeller 93 may be positioned below the showerhead 91. The propeller 93 may be positioned between the showerhead 91 and the stage 3.

The airflow generator 9 may include a rotary motor 95. The airflow generator 9 may include a first rotary motor 951. The first rotary motor 951 may force the propeller 93 to rotate in a clockwise direction or a counterclockwise direction. Referring to FIGS. 2 and 3, the first rotary motor 951 may include a first magnetic levitation motor 9511. The propeller 93 may use the first magnetic levitation motor 9511 to float in the first process space 1h. The first magnetic levitation motor 9511 may be configured to generate a magnetic field or force so that the propeller levitates or floats in the first process space. The propeller 93 may use a magnetic force to float in the first process space 1h. Hereinafter, the first rotation motor 951 and the first magnetic levitation motor 9511 may be omitted for convenience of drawing and description. However, no limitation is imposed on the position of the propeller 93 and the combination relationship between the propeller 93 and the first process chamber 1. Referring to FIG. 4, the propeller 93 may be combined with or provided as part of the first process chamber 1. The propeller 93 may be coupled to a top surface of the first process space 1h.

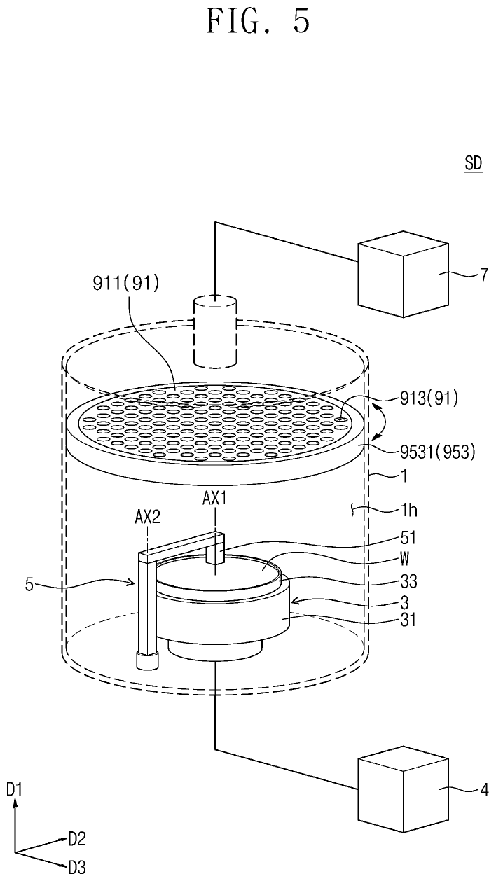

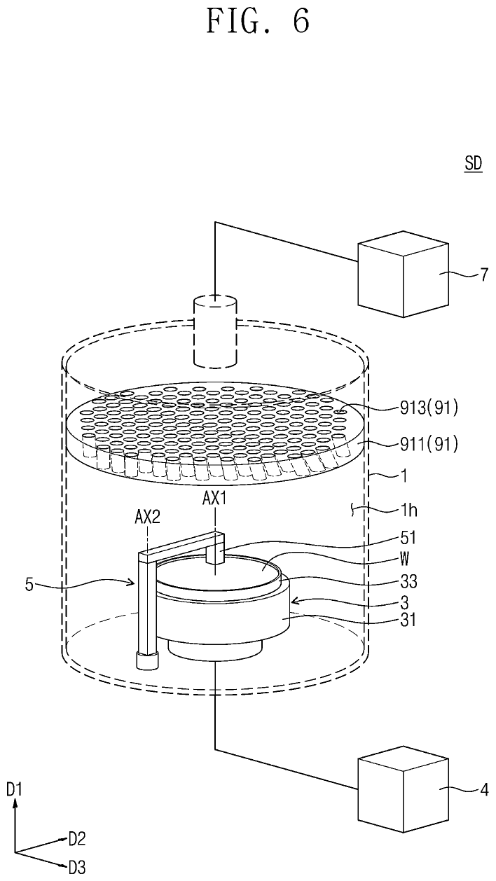

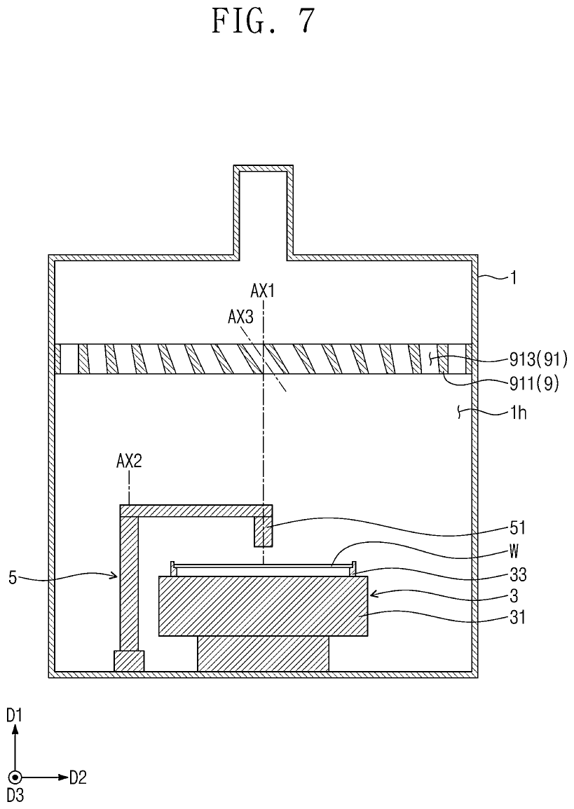

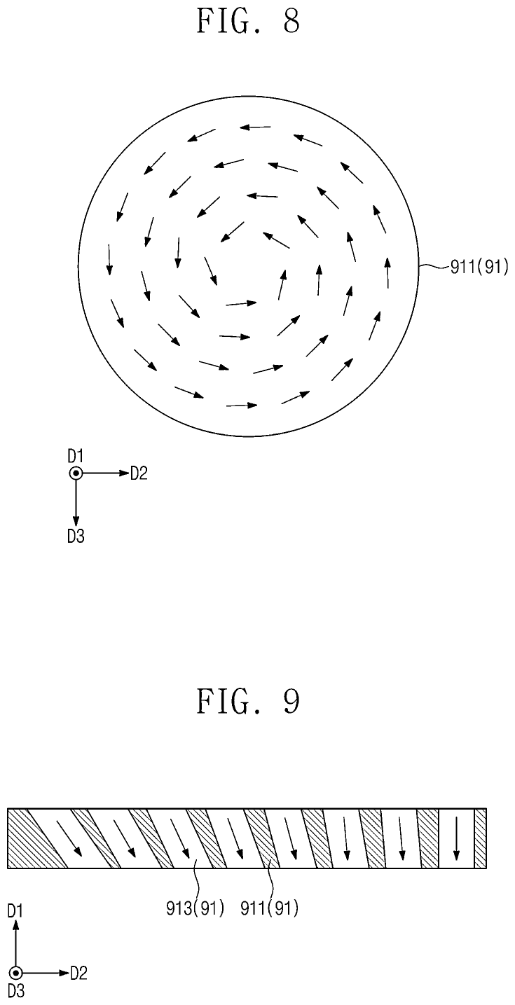

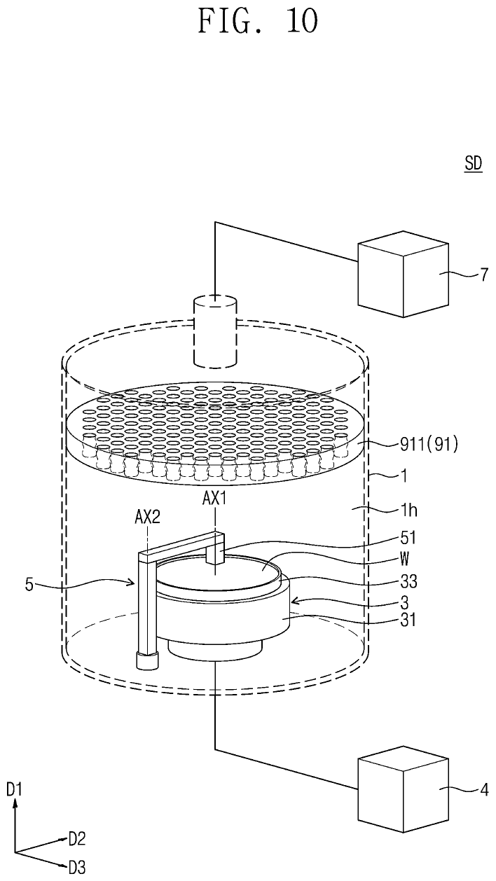

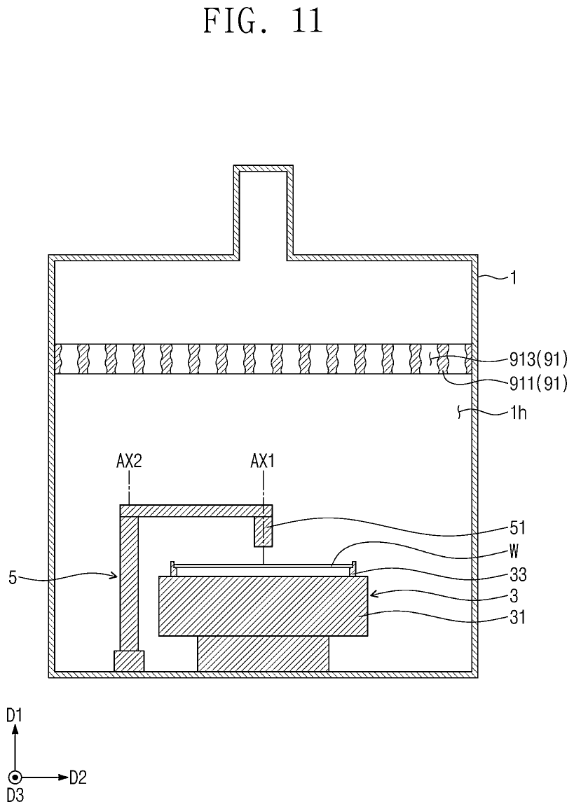

FIG. 5 illustrates a perspective view showing the substrate processing apparatus SD according to some embodiments of the present inventive concepts. FIG. 6 illustrates a perspective view showing the substrate processing apparatus SD according to some embodiments of the present inventive concepts. FIG. 7 illustrates a side view showing the substrate processing apparatus SD according to some embodiments of the present inventive concepts. FIG. 8 illustrates a plan view showing the showerhead 91 on which an extending direction of a gas hole 913 is expressed according to some embodiments of the present inventive concepts. FIG. 9 illustrates a side view showing the showerhead 91 according to some embodiments of the present inventive concepts. FIG. 10 illustrates a perspective view showing the substrate processing apparatus SD according to some embodiments of the present inventive concepts. FIG. 11 illustrates a cross-sectional view showing the substrate processing apparatus SD according to some embodiments of the present inventive concepts.

The airflow generator 9 may include the showerhead 91. An inert gas supplied from the gas supply unit 7 may be sprayed on the stage 3 through the showerhead 91. Referring to FIG. 5, the substrate processing apparatus SD may be provided which includes the showerhead 91 that rotates. The showerhead 91 may include a showerhead body 911. The showerhead body 911 may have a disk shape. The shape of the showerhead body 911, however, is not limited thereto. The showerhead 91 may provide a gas hole 913 through which an inert gas passes. The gas hole 913 may penetrate the showerhead body 911. The gas hole 913 may extend in a vertical direction or a direction of the first axis AX1. The shape of the gas hole 913, however, is not limited thereto. Another shape and extending direction of the gas hole 913 will be discussed below. The showerhead 91 may be connected to an inner lateral surface of the first process chamber 1. The airflow generator 9 may include a second rotary motor 953. The second rotary motor 953 may drive the showerhead 91 to rotate. The second rotary motor 953 may include a second magnetic levitation motor 9531.

The second magnetic levitation motor 9531 may cause the showerhead 91 to float in the first process space 1h. The second magnetic levitation motor 9531 may force the showerhead 91 to float while rotating in the first process space 1h. The second magnetic levitation motor 9531 may be configured to generate a magnetic field or force so that the showerhead 91 levitates or floats in the first process space The showerhead 91 may use a magnetic force to float in the first process space 1h. However, no limitation is imposed on the combination relationship between the showerhead 91 and the first process chamber 1. Hereinafter, the second rotation motor 953 and the second magnetic levitation motor 9531 may be omitted for convenience of drawing and description. The showerhead 91 may be combined with or provided as part of the inner lateral surface of the first process chamber 1. The showerhead 91 may extend from the inner lateral surface of the first process chamber 1 in a radius direction of the showerhead body 911. The showerhead 91 may overlap the inner lateral surface of the first process chamber 1. FIGS. 6, 7, 8, and 9 depict the substrate processing apparatus SD including the showerhead 91 with the gas hole 913 that has various shapes.

The variously shaped gas hole 913 may provide spiral-shaped fluidity to an inert gas supplied from the gas supply unit 7. Referring to FIGS. 6 and 7, the gas hole 913 may extend obliquely. A third axis AX3 parallel to an extending direction of the gas hole 913 may intersect the first axis AX1. The gas hole 913 may be provided in plural. The plurality of gas holes 913 may extend in a clockwise direction or a counterclockwise direction. The following will describe a single gas hole 913. Referring to FIGS. 8 and 9, the showerhead 91 may be illustrated in its plan view in which an extending direction of the gas hole 913 is expressed when the showerhead 91 is downwardly viewed. An arrow may have a start point that is a connection portion between the gas hole 913 and a top surface of the showerhead body 911. An arrow may have an end point that is a connection portion between the gas hole 913 and a bottom surface of the showerhead body 911.

When viewed above the showerhead 91, the plurality of gas holes 913 may extend in a counterclockwise direction. The extending direction of the plurality of gas holes 913, however, is not limited thereto. The plurality of gas holes 913 may extend in a direction capable of generating a spiral-shaped rotating air current in the first process space 1h. In this description, the rotating air current may indicate an airflow of inert gas. Referring to FIGS. 10 and 11, the gas hole 913 may have a helical shape. The shape of the gas hole 913, however, is not limited thereto. The gas hole 913 may have one of arc, helical, and wavy shapes each of which allows an inert gas to have spiral-shaped fluidity. The gas hole 913 may have any other suitable shapes to allow an inert gas to move in a spiral shape.

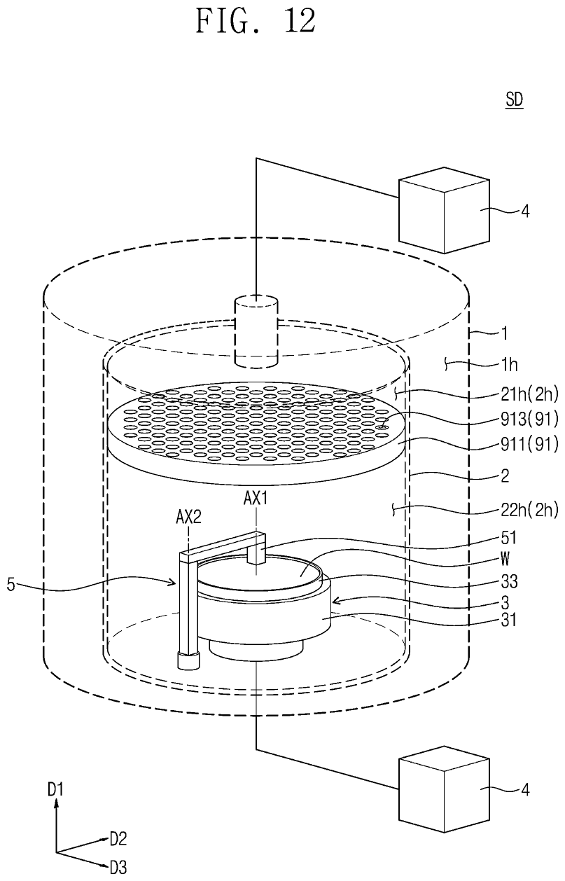

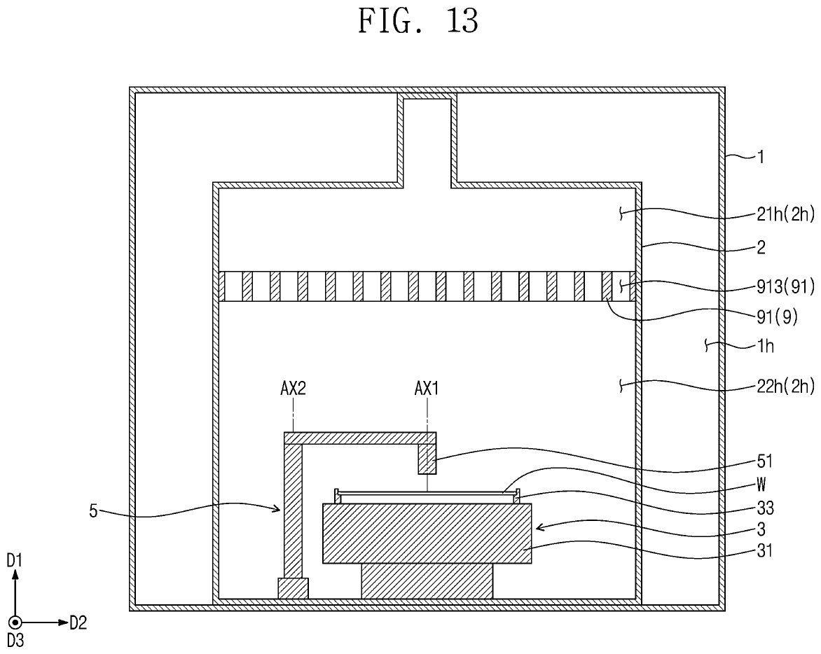

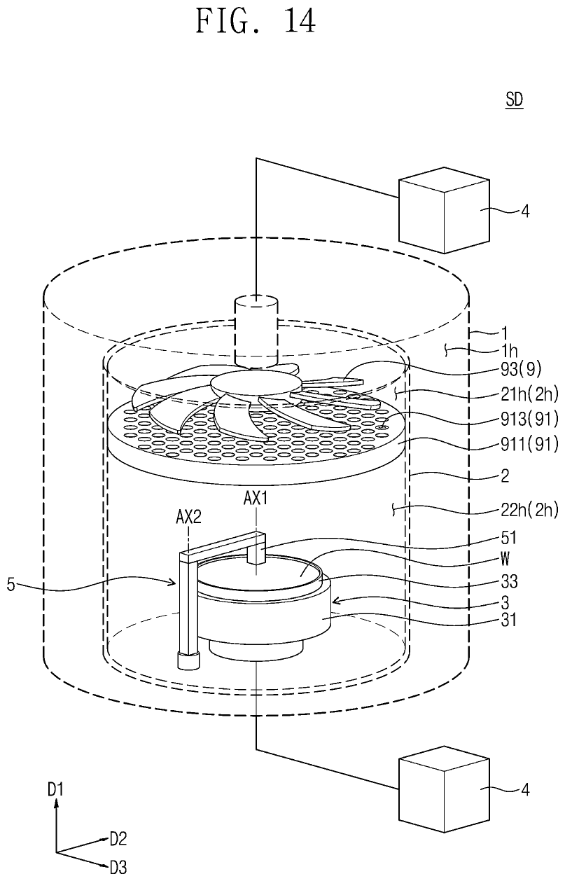

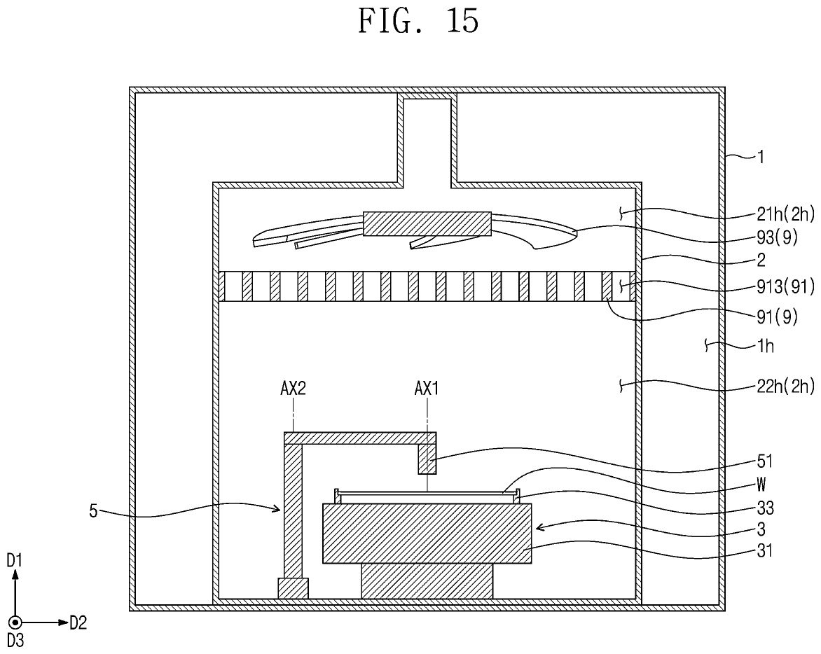

FIG. 12 illustrates a perspective view showing the substrate processing apparatus SD according to some embodiments of the present inventive concepts. FIG. 13 illustrates a cross-sectional view showing the substrate processing apparatus SD according to some embodiments of the present inventive concepts. FIG. 14 illustrates a perspective view showing the substrate processing apparatus SD according to some embodiments of the present inventive concepts. FIG. 15 illustrates a cross-sectional view showing the substrate processing apparatus SD according to some embodiments of the present inventive concepts.

Referring to FIGS. 12, 13, 14, and 15, the substrate processing apparatus SD may be provided which includes a second process chamber 2. The second process chamber 2 may be positioned in the first process chamber 1. The second process chamber 2 may have a volume less than that of the first process chamber 1. The second process chamber 2 may provide a second process space 2h. The second process space 2h may be a hermetically sealed space. When the second process chamber 2 is present, the second process space 2h may accommodate the stage 3, the cleaning nozzle arm 5, and the airflow generator 9. The gas supply unit 7 may be positioned on the second process chamber 2. The gas supply unit 7 may be associated with the second process chamber 2. The combination relationship between the second process chamber 2 and the stage 3, the cleaning nozzle arm 5, the airflow generator 9, and the gas supply unit 7 may be substantially the same as the combination relationship between the first process chamber 1 and the stage 3, the cleaning nozzle arm 5, the airflow generator 9, and the gas supply unit 7.

A description of the relationship between the first process chamber 1 and other components of the substrate processing apparatus SD in FIGS. 1 to 11 may be applicable to a description of the relationship between the second process chamber 2 and other components of the substrate processing apparatus SD. Referring to FIGS. 12 and 13, the airflow generator 9 may include the showerhead 91. The second rotary motor 953 may drive the showerhead 91 to rotate. The showerhead 91 may provide the gas hole 913 through which an inert gas passes. A configuration and operation of the showerhead 91 may be substantially the same as that discussed above. A shape and slope of the gas hole 913 may be substantially the same as that discussed above. The gas hole 913 may extend obliquely. The gas hole 913 may have one of arc, helical, and wavy shapes. The showerhead 91 may be connected to a lateral surface of the second process chamber 2. The second process space 2h may be divided by the showerhead 91. The second process space 2h may include a 2-1^{st} process space 21h on the showerhead 91 and a 2-2^{nd} process space 22h below the showerhead 91. The top surface of the showerhead body 911 may define the 2-1^{st} process space 21h. The gas supply unit 7 may supply the 2-1^{st} process space 21h with an inert gas. The bottom surface of the showerhead body 911 may define the 2-2^{nd} process space 22h. The stage 3 and the cleaning nozzle arm 5 may be in the 2-2^{nd} process space 22h.

Referring to FIGS. 14 and 15, the airflow generator 9 may include a showerhead 91 and a propeller 93. The propeller 93 may be positioned on the showerhead 91. The propeller 93 may be positioned in the 2-1^{st} process space 21h. The position of the propeller 93, however, is not limited thereto. The propeller 93 may be positioned below the showerhead 91. The propeller 93 may be positioned in the 2-2^{nd} process space 22h. The propeller 93 may be positioned between the showerhead 91 and the stage 3. A first rotary motor 951 may drive the propeller 93 to rotate. The position and operating method of the propeller 93 may be substantially the same as that discussed above.

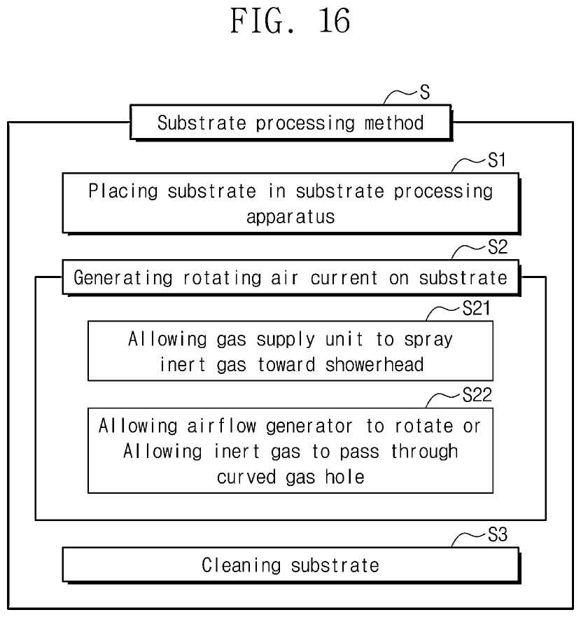

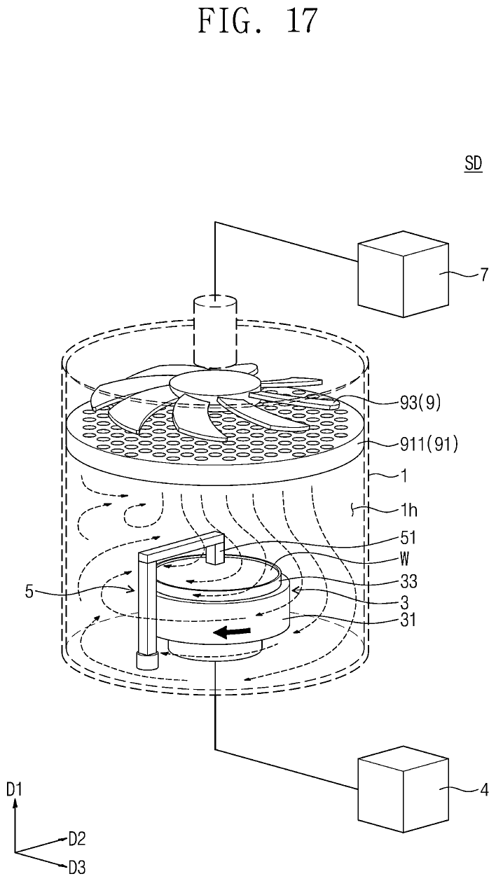

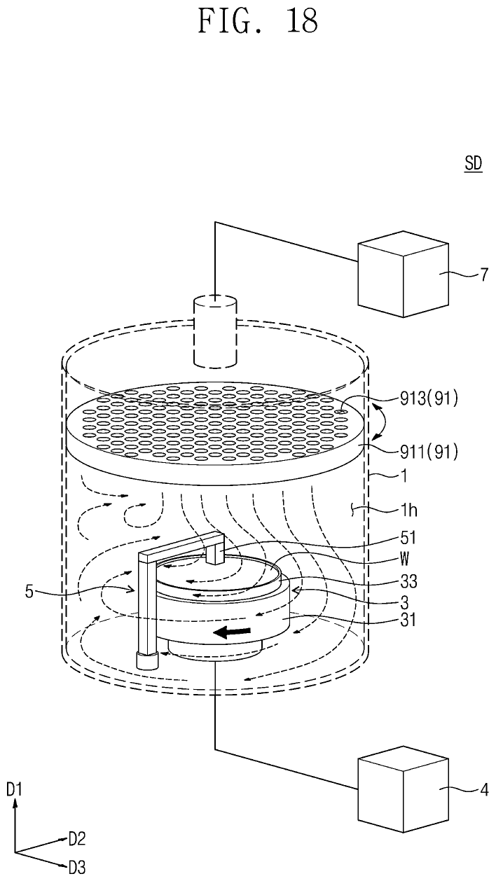

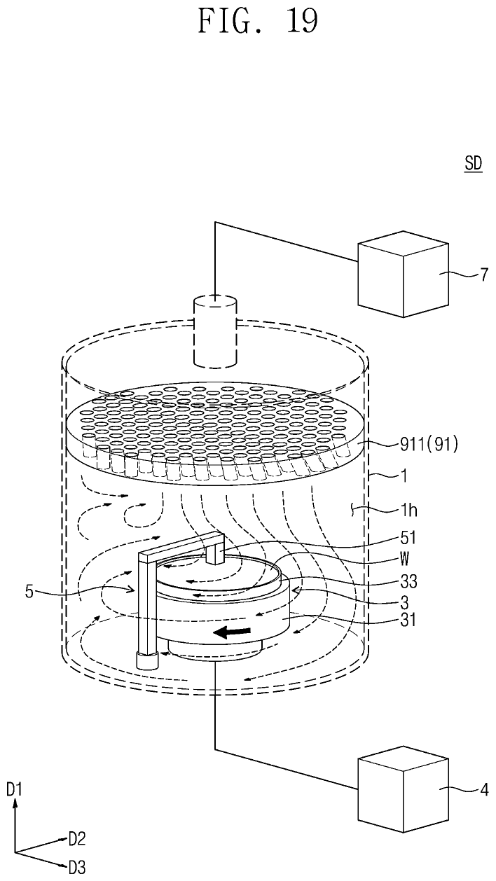

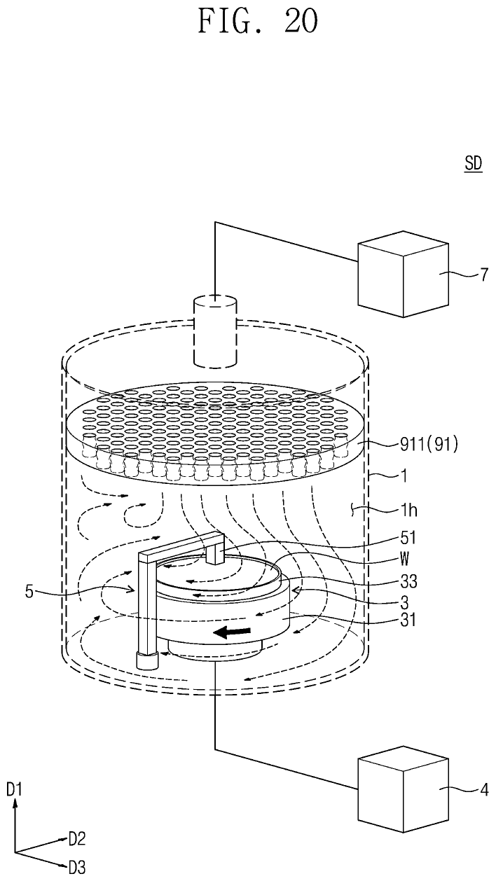

FIG. 16 illustrates a flow chart showing a substrate processing method S according to some embodiments of the present inventive concepts. FIG. 17 illustrates a perspective view showing the substrate processing apparatus SD according to some embodiments of the present inventive concepts. FIG. 18 illustrates a perspective view showing the substrate processing apparatus SD according to some embodiments of the present inventive concepts. FIG. 19 illustrates a perspective view showing the substrate processing apparatus SD according to some embodiments of the present inventive concepts. FIG. 20 illustrates a perspective view showing the substrate processing apparatus SD according to some embodiments of the present inventive concepts.

Referring to FIG. 16, the substrate processing method S may include placing the substrate W in the substrate processing apparatus SD (S1), generating a rotating air current on the substrate W (S2), and cleaning the substrate W (S3). The airflow generation step S2 may include allowing the gas supply unit 7 to spray an inert gas toward the showerhead 91 (S21). The airflow generation step S2 may include allowing the airflow generator 9 to rotate or allowing the inert gas to pass through the curved gas hole 913 (S22).

Referring to FIG. 17, the propeller 93 may rotate to generate the rotating air current in the first process space 1h. Referring to FIG. 18, the substrate processing apparatus SD may be provided which includes the showerhead 91 that rotates. The rotation of the showerhead 91 may generate the rotating air current in the first process space 1h. Referring to FIGS. 19 and 20, the gas hole 913 having various shapes may generate the rotating air current. The rotating air current may have a spiral shape. The inert gas may have more mobility in a horizontal direction in a case where the gas hole 913 extends obliquely than in a case where the gas hole 913 extends perpendicularly. When the gas hole 913 has a helical shape, the gas hole 913 may form a spiral-shaped rotating air current in the first process space 1h. The rotating air current may have any other suitable shapes capable of cleaning the substrate W. Referring to FIGS. 17, 18, 19, and 20, a rotation direction of the inert gas may be the same as that of the stage 3. The substrate cleaning step S3 may include coinciding the rotation direction of the stage 3 with that of the rotating air current. When the rotating air current rotates in a clockwise direction, the stage 3 may rotate in the clockwise direction. When the rotating air current rotates in a counterclockwise direction, the stage 3 may rotate in the counterclockwise direction

FIGS. 17, 18, 19, and 20 depict the formation of the rotating air current when the second process chamber 2 is absent. Referring to FIGS. 12, 13, 14, and 15, the second process chamber 2 may be positioned in the first process chamber 1. When the second process chamber 2 is present in the first process space 1h, the rotating air current of the inert gas may be created in the second process space 2h. When the second process chamber 2 is positioned in the first process chamber 1, the rotating air current may be created in the 2-2^{nd} process space 22h.

According to a substrate processing apparatus and a substrate processing method using the same in accordance with some embodiments of the present inventive concepts, foreign substances may be promptly cleaned from a surface of a substrate. An airflow generator may generate a rotating air current in a process space. The airflow generator may generate a rotating air current of inert gas in the process space. The rotating air current may be formed by rotation of a propeller. The rotating air current may be formed by rotation of a showerhead. As a gas hole of the showerhead has a curved shape, the inert gas may have a spiral-shaped rotating air current. As the inert gas has the spiral-shaped rotating air current, foreign substances on the substrate may be promptly swept. A rotation direction of a stage may be the same as that of the rotating air current of the inert gas. When the rotation direction of the rotating air current of the inert gas is the same as that of the stage, foreign substances on the substrate may be swept at high speeds. The rotating air current of the inert gas may compel a cleaning solution to be quickly dried and pushed outwardly from the substrate. The quick washing of the cleaning solution may suppress an oxidation reaction of the substrate caused by oxygen provided in the cleaning solution.

According to a substrate processing apparatus and a substrate processing method using the same in accordance with some embodiments of the present inventive concepts, there may be a reduction in time required for filling a process space with an inert gas. The inert gas may fill the process space before a substrate treatment process is performed. As a second process chamber is positioned in a first process chamber, the inert gas may fill only a second process space. A size of the second process chamber may determine a time required for filling the process space with the inert gas. A reduction in size of the second process chamber may cause an increase in speed for allowing the inert gas to fill the process space. A time required for filling the second process space with the inert gas may be about ⅕ a time required for filling the first process space with the inert gas. The second process chamber may cause that a time required for filling the process space with the inert gas is reduced by about 70% to about 80%.

According to a substrate processing apparatus and a substrate processing method using the same in accordance with some embodiments of the present inventive concepts, a chamber may be supplied with an inert gas during a cleaning procedure to reduce or prevent corrosion and substrate metal oxidation reactions caused by ambient oxygen and dissolved oxygen in a cleaning solution.

According to a substrate processing apparatus and a substrate processing method using the same of the present inventive concepts, an airflow generator may be included to generate a rotating air current in a process chamber.

According to a substrate processing apparatus and a substrate processing method using the same of the present inventive concepts, a rotating air current may be created to effectively eliminate foreign substances on a substrate.

According to a substrate processing apparatus and a substrate processing method using the same of the present inventive concepts, a propeller or a showerhead may be included.

According to a substrate processing apparatus and a substrate processing method using the same of the present inventive concepts, there may be a reduction in volume of a process space to be filled with an inert gas.

Effects of the present inventive concepts are not limited to the mentioned above, other effects which have not been mentioned above will be clearly understood to those skilled in the art from the following description.

Although the present invention has been described in connection with some embodiments of the present inventive concepts illustrated in the accompanying drawings, it will be understood to those skilled in the art that various changes and modifications may be made without departing from the technical spirit and essential feature of the present inventive concepts. It therefore will be understood that the embodiments described above are just illustrative but not limitative in all aspects.

What is claimed is:

1. A substrate processing apparatus, comprising:
a first process chamber including a first process space;
a stage in the first process space, the stage being configured to support a substrate;
a stage driving mechanism configured to drive the stage to rotate about a first axis;
a cleaning nozzle arm configured to supply a cleaning solution onto the stage;
a gas supply unit configured to provide an inert gas to the first process space; and
an airflow generator between the stage and the gas supply unit, the airflow generator being configured to generate a spiral-shaped rotating air current.

2. The apparatus of claim 1, wherein the airflow generator includes a rotatable propeller.

3. The apparatus of claim 1, wherein the airflow generator includes a showerhead configured to provide a gas hole through which the inert gas passes.

4. The apparatus of claim 2, wherein
the airflow generator is rotatable, and
the airflow generator includes a magnetic levitation motor configured to generate a magnetic force that is configured to cause the propeller to float in the first process space.

5. The apparatus of claim 1, wherein the gas supply unit is configured to supply one of nitrogen (N₂), argon (Ar), and helium (He) on the airflow generator.

6. The apparatus of claim 3, wherein
the gas hole extends obliquely, and
the first axis and a second axis intersect each other, the second axis being parallel to an extending direction of the gas hole.

7. The apparatus of claim 1, further comprising a second process chamber in the first process chamber,
wherein the second process chamber is configured to provide a second process space,
wherein the stage, the cleaning nozzle arm, and the airflow generator are in the second process space, and
wherein the gas supply unit is on the second process chamber.

8. The apparatus of claim 7, wherein the airflow generator includes a showerhead connected to a lateral surface of the second process chamber.

9. The apparatus of claim 8, wherein the airflow generator includes:
a propeller on the showerhead; and
a rotary motor configured to rotate the propeller or the showerhead.

10. The apparatus of claim 8, wherein the showerhead is configured to provide a gas hole having one of arc, helical, and wavy shapes, each of which is configured to allow the inert gas to have spiral-shaped fluidity, the gas supply unit configured to supply the inert gas.

11. A substrate processing apparatus, comprising:
a first process chamber including a first process space;
a stage in the first process space, the stage configured to support a substrate;
a cleaning nozzle arm in the first process space and upwardly spaced apart from the stage;
a gas supply unit configured to supply the first process space with an inert gas; and
an airflow generator on the stage, the airflow generator configured to create a spiral-shaped rotating air current,
wherein the airflow generator includes a showerhead comprising a gas hole configured to uniformly spray the inert gas on the stage.

12. The apparatus of claim 11, wherein the gas hole has one of arc, helical, and wavy shapes.

13. The apparatus of claim 11, wherein the airflow generator further includes a rotatable propeller on the showerhead,
wherein the propeller and the showerhead are a part of the first process chamber.

14. The apparatus of claim 11, wherein the airflow generator further includes a rotatable propeller on the showerhead,
wherein one of the propeller and the showerhead is configured to utilize a magnetic force to float in the first process space.

15. The apparatus of claim 11, wherein the airflow generator includes a rotary motor configured to rotate the showerhead,
wherein the rotary motor includes a magnetic levitation motor.

16. The apparatus of claim 11, further comprising a second process chamber including a second process space,
wherein the stage, the cleaning nozzle arm, and the airflow generator are in the second process space, and
wherein the second process space includes:
a 2-1^{st} process space defined by a top surface of the showerhead; and
a 2-2^{nd} process space defined by a bottom surface of the showerhead.

17. The apparatus of claim 16, wherein
the gas supply unit is provided as part of a top surface of the second process chamber,
the gas supply unit provides the inert gas to the 2-1^{st} process space; and
the stage and the cleaning nozzle arm are in the 2-2^{nd} process space.

18. A substrate processing apparatus, comprising:
a first process chamber including a first process space;
a rotatable stage in the first process space;
a cleaning nozzle arm configured to supply a cleaning solution onto the stage;
a gas supply unit configured to supply the first process space with an inert gas; and
an airflow generator on the stage, the airflow generator configured to generate the rotating air current, wherein the rotating air current is spiral-shaped,
wherein the airflow generator includes a showerhead and a magnetic levitation motor,
wherein the showerhead comprising a gas hole through which the inert gas passes,
wherein the magnetic levitation motor configured to generate a magnetic force that is configured to cause the showerhead to float in the first process space.

19. The apparatus of claim 18, further includes a stage driving mechanism configured to drive the stage to rotate,
wherein a rotation direction of the stage is same as a rotation direction of the rotating air current.

20. The apparatus of claim 18, further includes a second process chamber in the first process chamber, the second process chamber configured to provide a second process space that is hermetically sealed,
wherein the stage, the airflow generator, and the cleaning nozzle arm are in the second process space.
